(19) United States
(12) Patent Application Publication
(10) Pub. No.: US 2024/0178044 A1
(43) Pub. Date: May 30, 2024

(54) TRANSFER SYSTEM, PROCESSING SYSTEM, AND TRANSFER METHOD

(71) Applicant: Tokyo Electron Limited, Tokyo (JP)

(72) Inventors: Kento TOKAIRIN, Miyagi (JP); Genichi NANASAKI, Miyagi (JP); Hideyuki OSADA, Miyagi (JP)

(73) Assignee: Tokyo Electron Limited, Tokyo (JP)

(21) Appl. No.: 18/524,082

(22) Filed: Nov. 30, 2023

(30) Foreign Application Priority Data
Nov. 30, 2022 (JP) 2022-191936

(51) Int. Cl. H01L 21/687; B25J 11/00; B25J 13/08; H01L 21/67; H01L 21/677

(52) U.S. Cl. CPC H01L 21/68707; B25J 11/0095; B25J 13/088; H01L 21/67259; H01L 21/67769

(57) ABSTRACT

Provided is a transfer system comprising a transfer robot configured to transfer an object to be transferred; a storage part configured to store the object to be transferred by the transfer robot; a state detection sensor configured to detect positional misalignment of the object to be transferred stored in the storage part; and a controller configured to control an operation of the transfer robot, wherein the transfer robot has a position detection sensor configured to detect a position of the object to be transferred placed in the storage part, and the controller controls determining, whether or not the misaligned object to be transferred is collectable based on the detection result of the state detection sensor; operating the transfer robot and detecting the position of the object to be transferred by the position detection sensor; and collecting the misaligned object to be transferred by the transfer robot.

### CROSS-REFERENCE TO RELATED APPLICATION

This application claims priority to Japanese Patent Application No. 2022-191936, filed on Nov. 30, 2022, the entire contents of which are incorporated herein by reference.

### TECHNICAL FIELD

The present disclosure relates to a transfer system, a processing system, and a transfer method.

### BACKGROUND

Japanese Laid-open Patent Publication No. 2021-141136 discloses an atmospheric transfer module (transfer system) including a transfer robot and a storage module. The transfer robot transfers a substrate before or after processing to the storage module, and temporarily sets the substrate in a standby state.

Further, Japanese Laid-open Patent Publication No. 2021-129023 discloses a transfer arm disposed in a loader module (transfer system) and having a bifurcated pick. The pick has a suction hole that applies an attraction pressure to a substrate in order to hold the substrate during transfer.

### SUMMARY

The present disclosure provides a technique capable of reducing a user's workload even when positional misalignment occurs in an object to be transferred.

In accordance with an aspect of the present disclosure, there is provided a transfer system comprising a transfer robot configured to transfer an object to be transferred; a storage part configured to store the object to be transferred by the transfer robot; a state detection sensor configured to detect positional misalignment of the object to be transferred stored in the storage part; and a controller configured to control an operation of the transfer robot, wherein the transfer robot has a position detection sensor configured to detect a position of the object to be transferred placed in the storage part, and the controller controls transferring the object to be transferred by the transfer robot and placing the object to be transferred in the storage part; determining, after said placing the object to be transferred, whether or not the misaligned object to be transferred is collectable based on the detection result of the state detection sensor; operating the transfer robot and detecting the position of the object to be transferred by the position detection sensor when it is possible to collect the misaligned object to be transferred; and moving the transfer robot based on the detected position of the object to be transferred and collecting the misaligned object to be transferred by the transfer robot.

### BRIEF DESCRIPTION OF THE DRAWINGS

FIG. 1 is a plan view partially showing a processing system according to an embodiment.

FIG. 2 is an enlarged perspective view of a pick of a transfer robot.

FIG. 3 is a perspective view of a storage module.

FIG. 4A is a first schematic diagram showing a cause of positional misalignment of a substrate accommodated in the storage module.

FIG. 4B is a second schematic diagram showing a cause of positional misalignment of a substrate accommodated in the storage module.

FIG. 5A is a first explanatory diagram showing a state of positional misalignment of a substrate in the storage module.

FIG. 5B is a first explanatory diagram showing a state of positional misalignment of a substrate in the storage module.

FIG. 6A is a first operation diagram showing placing of a substrate on a placing table of a retreat module.

FIG. 6B is a second operation diagram showing placing of a substrate on the placing table of the retreat module.

FIG. 7 is a block diagram showing functional blocks in a controller.

FIGS. 8A to 8D are first to fourth operational diagrams showing a search operation process for searching for the amount of positional misalignment of a substrate.

FIG. 9 is a flowchart showing main processing flow of a transfer method.

FIG. 10 is a flowchart showing a positional misalignment handling routine.

FIG. 11A shows an operation of attracting and holding a substrate by a transfer robot.

FIG. 11B shows an operation of holding a substrate by a transfer robot without attracting the substrate.

FIG. 12 is a flowchart showing a positional misalignment handling routine of a transfer method according to a modification.

### DETAILED DESCRIPTION

Hereinafter, embodiments of the present disclosure will be described with reference to the accompanying drawings. Like reference numerals will be given to like parts throughout the drawings.

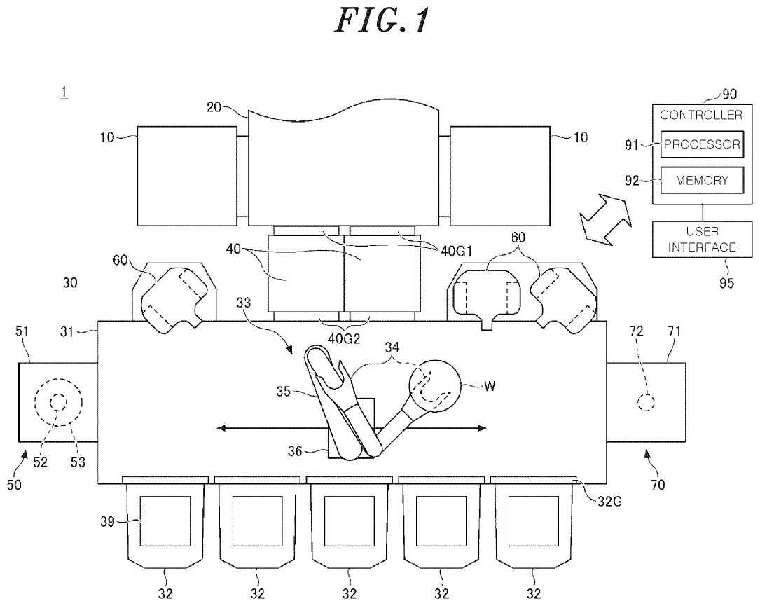

FIG. 1 is a plan view showing a configuration of a processing system 1 according to an embodiment. In FIG. 1, for convenience, some of internal components of some devices are illustrated transparently for easier understanding. The processing system 1 is a substrate processing system that transfers a substrate W, which is an example of an object to be transferred, and performs various substrate treatments on the substrate W. The substrate W processed in the processing system 1 may include a silicon wafer such as single crystal silicon, silicon carbide and an SOI wafer, and a compound semiconductor wafer such as a GaAs wafer, an SiC wafer, a GaN wafer and an InP wafer.

The processing system 1 includes multiple processing modules 10, a vacuum transfer module 20, an atmospheric transfer module 30, and multiple load-lock modules 40. The processing system 1 further includes a controller 90 that controls each module.

Each of the processing modules 10 has a processing chamber that can be depressurized to a vacuum atmosphere, and actually performs various substrate treatments (etching, film formation, ashing, and the like) on a substrate W accommodated in the processing chamber. The term “vacuum” in this specification refers to a pressure lower than an atmospheric pressure. The processing module 10 may be a plasma processing module that performs plasma processing on a substrate W. Although FIG. 1 shows two processing modules 10, the number of processing modules 10 may be one, or may be three or more. Further, the processing modules 10 may perform same substrate treatment or different substrate treatments.

The vacuum transfer module 20 has a vacuum transfer chamber in which a vacuum transfer robot (not shown) for transferring a substrate W is installed. The processing modules 10 and the load-lock modules 40 are connected to the vacuum transfer chamber. In the vacuum transfer module 20, a pressure in the vacuum transfer chamber is reduced to a vacuum atmosphere, so that the substrate W is transferred between the processing module 10 and the load-lock module 40 or between the processing modules 10 by the vacuum transfer robot.

The load-lock module 40 is connected to the vacuum transfer module 20 via a gate valve 40G1 and is connected to the atmospheric transfer module 30 via a gate valve 40G2. Although the processing system 1 has two load-lock modules 40 installed side by side between the vacuum transfer module 20 and the atmospheric transfer module 30 in FIG. 1, the number of load-lock modules 40 may be one or may be more than 2.

The load-lock module 40 has a chamber of which inner pressure can be switched between a vacuum state and an atmospheric pressure. A stage (not shown) on which the substrate W can be placed is disposed in the chamber of which inner pressure is variable. In the case of loading the substrate W from the atmospheric transfer module 30 to the vacuum transfer module 20, the substrate W is transferred from the atmospheric transfer module 30 into the chamber of which inner pressure is variable, which is maintained at an atmospheric pressure; the pressure in the chamber of which inner pressure is variable is decreased; and the substrate W is loaded into the vacuum transfer module 20. In the case of unloading the substrate W from the vacuum transfer module 20 to the atmospheric transfer module 30, the substrate W is transferred from the vacuum transfer module 20 into the chamber of which inner pressure is variable, which is maintained in a vacuum state; the pressure in the chamber of which inner pressure is variable is increased; and the substrate W is loaded into the atmospheric transfer module 30.

The atmospheric transfer module 30 constitutes a transfer system for transferring the substrate W on an atmospheric pressure side (atmospheric pressure atmosphere) with respect to the vacuum transfer module 20. The atmospheric transfer module 30 has an atmospheric transfer chamber 31 in which an atmospheric transfer robot (hereinafter, simply referred to as “transfer robot 33”) is installed. The atmospheric transfer chamber 31 has a rectangular shape in a plan view. The atmospheric transfer chamber 31 is provided with multiple (five) load ports 32, and is connected to an aligner module 50, multiple storage modules 60, and a retreat module 70. The atmospheric transfer module 30 may be, for example, an equipment front end module (EFEM). Further, the atmospheric transfer module 30 may include a fan filter unit (FFU) that supplies clean air from the top of the atmospheric transfer chamber 31, and an exhaust device that exhausts air.

A substrate storage case 39 (accommodating part) such as a front opening unified pod (FOUP) capable of accommodating multiple substrates W is set in each of the load ports 32. A gate 32G that can be opened and closed is disposed between the atmospheric transfer chamber 31 and each load port 32. Although FIG. 1 shows five load ports 32, the number of load ports 32 is not particularly limited.

The transfer robot 33 transfers the substrate W in the atmospheric transfer chamber 31. The transfer robot 33 includes, for example, a bifurcated pick 34 that directly holds the substrate W, multiple arms 35 that support the pick 34 such that the position of the pick 34 can be displaced, and a base 36 that supports the arm 35. The transfer robot 33 may be configured to reciprocate along a longitudinal direction of the atmospheric transfer chamber 31 by a slide mechanism (not shown) disposed at the base 36. Further, the base 36 is provided with a lifting mechanism (not shown) that can move the arm 35 and the pick 34 together in a vertical direction. The arms 35 rotate relative to each other based on joints that connect the arms 35, thereby moving the picks 34 constituting an end effector of the transfer robot 33 to a predetermined horizontal position. The transfer robot 33 of the present embodiment includes multiple (two) picks 34, and each pick 34 can individually transfer the substrate W.

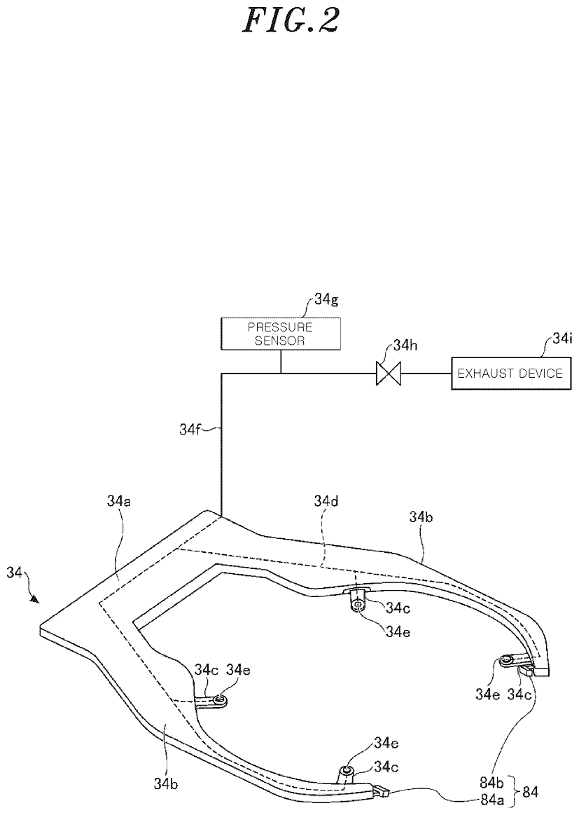

FIG. 2 is an enlarged perspective view of one pick 34 of the transfer robot 33. The pick 34 has a base portion 34a, finger portions 34b, claw portions 34c, and a suction passage 34d. The base portion 34a is attached to an arm 35 on a base end side among the arms 35. The finger portions 34b extend in a substantially arc shape from the base portion 34a toward the tip end side (direction opposite to the connected arm 35). The claw portions 34c project toward the central portion of the area (hereinafter, referred to as “substrate holding area”) surrounded by the base portion 34a and the finger portions 34b. The four claw portions 34c are spaced apart from each other at intervals along the circumferential direction of the substrate holding area. Suction holes 34e are formed at the upper parts of the claw portions 34c. In the case of holding the substrate W, the transfer robot 33 places the peripheral portion of the backside of the substrate W on the claw portions 34c to close the suction holes 34e, and applies an attraction pressure from the suction holes 34e. The suction passage 34d is formed in the base portion 34a and the finger portions 34b. One end of the suction passage 34d is connected to the suction holes 34e of the claw portions 34c, and the other end of the suction passage 34d communicates with an exhaust line 34f connected to the pick 34.

The exhaust line 34f is provided with a pressure sensor 34g, which is a pressure detector, and a valve 34h. The pressure sensor 34g detects the attraction pressure in the exhaust line 34f, and transmits a signal of the detected pressure to the controller 90. An exhaust device 34i is connected to the downstream side of the valve 34h of the exhaust line 34f. The exhaust device 34i includes a regulator, a vacuum pump, or the like, and adjusts the pressure in the suction passage 34d and the exhaust line 34f by conducting suction from the suction passage 34d and the exhaust line 34f. For example, under the control of the controller 90, the valve 34h is opened during a period from immediately before the transfer robot 33 receives the substrate W from one module to immediately before the substrate W is placed on another module, and closed during other times.

A position detection sensor 84 functioning as a mapping sensor is disposed at the tip end of the finger portion 34b of the pick 34. The position detection sensor 84 detects the substrate W placed in the substrate storage case 39 of the load port 32 or the storage module 60 based on the operation of the transfer robot 33, and transmits the detection result to the controller 90.

In the present embodiment, the position detection sensor 84 has a light transmitting portion 84a and a light receiving portion 84b that are arranged to face each other in the horizontal direction. The light transmitting portion 84a is disposed at the tip end of one finger portion 34b of the pick 34, and emits detection light toward the light receiving portion 84b. The light receiving portion 84b is disposed at the tip end of the other finger portion 34b of the pick 34, and receives the detection light emitted by the light transmitting portion 84a. If the detection light emitted by the light transmitting portion 84a is not received by the light receiving portion 84b, the position detection sensor 84 determines that the substrate W exists between the light transmitting portion 84a and the light receiving portion 84b, and transmits information indicating that the substrate W exists to the controller 90. The positional relationship between the light transmitting portion 84a and the light receiving portion 84b may be reversed.

Referring back to FIG. 1, the transfer robot 33 configured as described above transfers the substrate W from the module where the substrate W is received to the module where the substrate W is delivered under the control of the controller 90. The module where the substrate W is received and the module where the substrate W is delivered may be the load ports 32, the load-lock modules 40, the aligner module 50, the storage modules 60, and the retreat module 70.

The aligner module 50 is connected to one longitudinal end of the atmospheric transfer chamber 31 and aligns the substrate W transferred by the transfer robot 33. The aligner module 50 includes, for example, a housing 51 capable of accommodating a substrate W, a rotation stage 52 disposed in the housing 51 and on which the substrate W can be placed, and a rotation driving mechanism 53 that rotates the rotation stage 52. Further, an optical sensor (not shown) for optically detecting the peripheral edge of the substrate W is disposed above the outer periphery of the rotation stage 52. The optical sensor optically measures the peripheral edge of the rotating substrate W and detects the position of a notch (or an orientation flat) formed at the substrate W.

The housing 51 is opened toward the atmospheric transfer chamber 31, and the transfer robot 33 can access the inside thereof. The rotation stage 52 has a diameter smaller than that of the substrate W, and the center of the substrate W is placed on the upper surface. The aligner module 50 detects the notch or the deviation of the peripheral edge of the substrate W rotated by the rotation driving mechanism 53, and calculates the orientation or the positional misalignment of the substrate W. When the transfer robot 33 receives the substrate from the aligner module 50, the controller 90 corrects the orientation or the positional misalignment of the substrate W.

The storage modules 60 are accommodating parts that temporarily hold substrates W before or after processing. The storage modules 60 are disposed, for example, on the longitudinal side of the atmospheric transfer chamber 31 to which the load-lock modules 40 are connected. Although FIG. 1 shows three storage modules 60, the number of storage modules 60 may be one or two, or may be four or more.

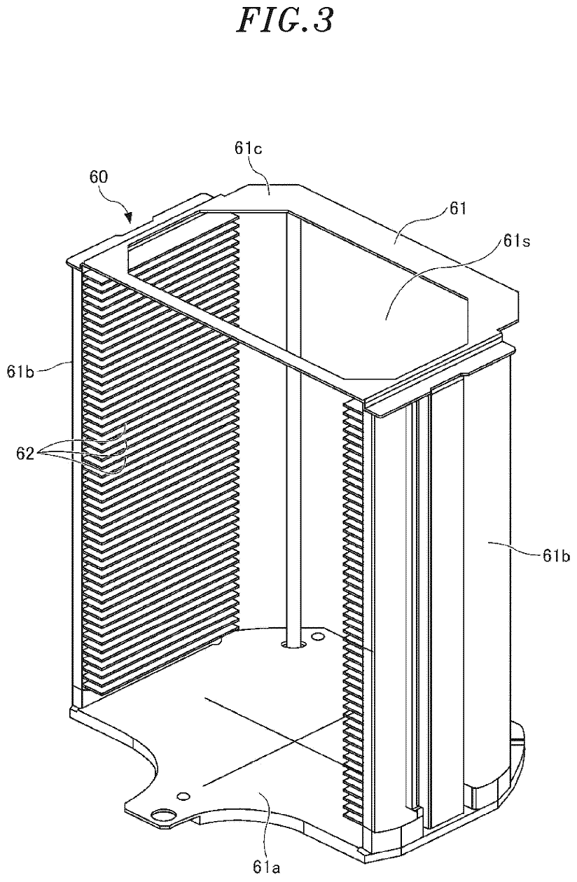

FIG. 3 is a perspective view showing an example of the storage module 60. The storage module 60 includes a frame housing 61 having a bottom wall 61a, a pair of sidewalls 61b, and a ceiling frame 61c, and multiple shelf boards 62 disposed on the inner sides (facing surface sides) of the sidewalls 61b. A space 61s capable of accommodating multiple substrates W along the vertical direction is formed in the frame housing 61. The space 61s communicates with the space of the atmospheric transfer chamber 31 via an opening between the pair of sidewalls 61b.

The shelf boards 62 disposed on the sidewall 61b are arranged at equal intervals along the vertical direction of the frame housing 61, and projected by a short distance from the inner surfaces of the sidewalls 61b toward the center in the width direction. The storage module 60 supports a part of the peripheral edge of the substrate W by the pair of shelf boards 62 disposed at the same height on the pair of sidewalls 61b. The interval between multiple shelf boards 62 arranged in the vertical direction is set to be larger than the sum of the thickness of the substrate W and the thickness of the pick 34 of the transfer robot 33, and has an appropriate margin that allows the transfer robot 33 to be displaced vertically.

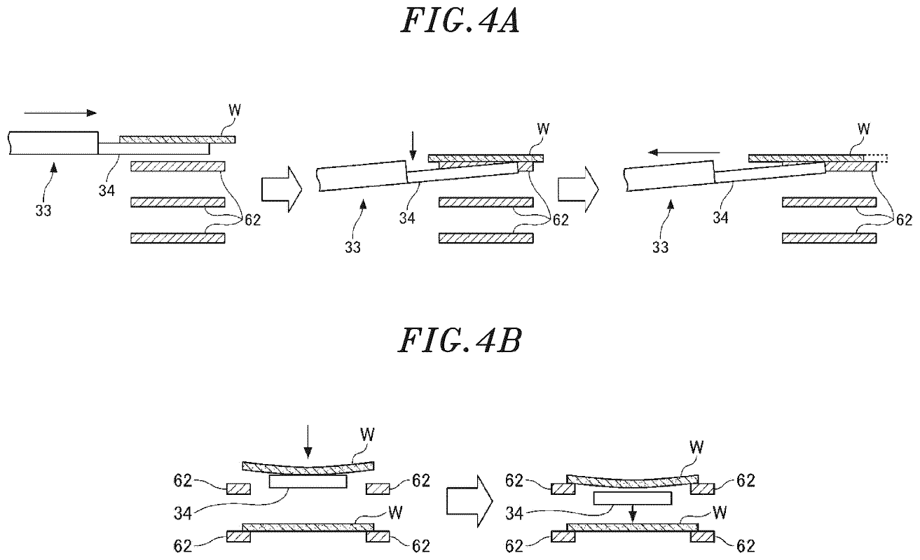

The transfer robot 33 enters the space 61s through the opening of the frame housing 61 by sliding the substrate W held by the pick 34, and loads the substrate W into the storage module 60 by lowering the substrate W onto the pair of shelf boards 62 (see also FIG. 4A). On the contrary, the transfer robot 33 moves an empty pick 34 to a position below the substrate W held by the pair of shelf boards 62 and unloads the substrate W from the storage module 60 by lifting the pick 34.

FIG. 4A is a first schematic diagram showing the positional misalignment of the substrates W stored in the storage module 60. FIG. 4B is a second schematic diagram showing the positional misalignment of the substrates W stored in the storage module 60. Next, the positional misalignment of the substrate W that occurs during the transfer using the pick 34 of the transfer robot 33 will be described.

As shown in FIG. 4A, when the transfer robot 33 holds the substrate W and loads the substrate W into the storage module 60, the pick 34 attracts and holds the substrate W. In this case, even if the attraction by the exhaust device 34i is stopped, the substrate W and the pick 34 may remain in close contact with each other. In this case, even if the pick 34 is lowered to a position below the pair of shelf boards 62 in order to transfer the substrates W to the pair of shelf boards 62, the tip ends of the pick 34 remain in close contact with the backside of the substrate W. If the transfer robot 33 is moved backward in a state where the tip ends of the pick 34 remain in close contact with the substrate W, the substrate W moves relative to the storage module 60, which causes positional misalignment of the substrate W. For example, the substrate W is misaligned in a direction projecting from the storage module 60 toward the atmospheric transfer chamber 31 until the close contact with the transfer robot 33 is released.

Further, as shown in FIG. 4B, if the distortion of the substrate W such as warpage or the like occurs, the central portion of the substrate W is supported while being lowered downward in a state where the substrate W is placed on the pair of shelf boards 62. In this case, the margin (interval) for displacing the transfer robot 33 downward becomes smaller, so that it is difficult to release the close contact with the substrate W. Further, when the pick 34 retreats, the pick 34 interferes with the substrate W disposed thereabove or therebelow, which may cause positional misalignment of the substrate W.

As described above, when the substrate W is misaligned with respect to the storage module 60, it affects the holding and unloading of the substrate W by the transfer robot 33 (the collision of the substrate W with other components, the damage on the substrate W due to falling of the substrate W). It is possible to notify a user of an error after the detection of the projection of the substrate W, stop the apparatus, and collect the substrate W. However, in this case, a user's workload increases, and the downtime of the apparatus increases.

The processing system 1 (the atmospheric transfer module 30) of the present embodiment monitors the positional misalignment of the substrate W after the transfer robot 33 transfers the substrate W. If the substrate W is misaligned, a process for eliminating the misalignment of the substrate W is performed. Hereinafter, such a configuration will be specifically described.

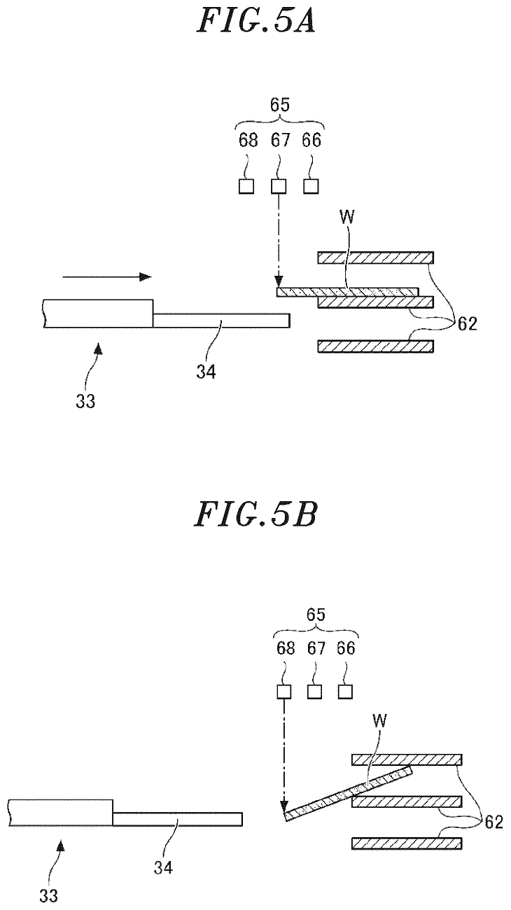

FIG. 5A is a first explanatory diagram showing a positional misalignment state of the substrate W in the storage module 60. FIG. 5B is a first explanatory diagram showing a positional misalignment state of the substrate W in the storage module 60. The atmospheric transfer module 30 has a state detection sensor 65 to monitor the positional misalignment of the substrate W with respect to the storage module 60. The state detection sensor 65 may be disposed at the storage module 60, or may be disposed in the atmospheric transfer chamber 31 near the storage module 60 (for example, the placing portion on which the storage module 60 is placed, the ceiling of the atmospheric transfer chamber, or the like). Hereinafter, a case where the detection is performed using the state detection sensor 65 disposed at the ceiling of the atmospheric transfer chamber 31 will be described.

The state detection sensor 65 includes, for example, a projection determining sensor 66, a correction determining sensor 67, and a collection determining sensor 68. The projection determining sensor 66, the correction determining sensor 67, and the collection determining sensor 68 are disposed in that order in a direction distant from the substrate W (the storage module 60) placed on the pair of shelf boards 62. The projection determining sensor 66, the correction determining sensor 67, and the collection determining sensor 68 may be disposed side by side along the normal line extending from the peripheral edge of the substrate W, or may be provided at different positions.

In other words, among the state detection sensors 65, the projection determining sensor 66 is disposed at a position closest to the substrate W. The projection determining sensor 66 detects whether or not the substrate W projects (is misaligned) with respect to the reference placing position at which the substrate W is loaded on the storage module 60.

The correction determining sensor 67 is disposed at a position distant from the substrate W compared to the projection determining sensor 66. The distance between the correction determining sensor 67 and the substrate W may be greater than the distance between the projection determining sensor 66 and the substrate W by several mm to several cm, for example. The correction determining sensor 67 is a detector for detecting whether or not the correction for eliminating the positional misalignment of the misaligned substrate W is necessary.

The collection determining sensor 68 is disposed at a position further distant from the substrate W compared to the correction determining sensor 67. For example, the collection determining sensor 68 may be installed at a position that is more than a radius of the substrate W away from the outer edge of the substrate W placed in the reference placing position. Accordingly, the collection determining sensor 68 can detect a substrate W that is misaligned by the distance greater than or equal to the radius. If the positional misalignment occurs by a distance greater than or equal to the radius, it is assumed that the substrate W is supported while being inclined with respect to the storage module 60 (see FIG. 5B). On the other hand, if the positional misalignment occurs by a distance less than the radius, it is assumed that the substrate W is supported horizontally with respect to the storage module 60 (see FIG. 5A).

A detector capable of optically detecting whether or not the substrate W exists can be applied to the projection determining sensor 66, the correction determining sensor 67, and the collection determining sensor 68. For example, the detector may be one for detecting transmission/blocking of light using a light emitting element and a light receiving element, one for detecting the reflection intensity of light using a light emitting element and a light receiving element, or the like.

As shown in FIG. 5A, when the correction determining sensor 67 detects the projection of the substrate W and the collection determining sensor 68 does not detect the projection of the substrate W, the controller 90 determines whether or not to perform a process of collecting the substrate W using the transfer robot 33 and performing correction. On the other hand, as shown in FIG. 5B, when the collection determining sensor 68 detects the projection of the substrate W, the controller 90 determines that the transfer robot 33 cannot collect the substrate W. In other words, when the collection determining sensor 68 detects the substrate W, it may be considered that the substrate W is obliquely held due to the projection of the substrate W. In this case, even if the pick 34 is moved to a position below the substrate W to collect the substrate W, the pick 34 is brought into contact with the inclined substrate W when the pick 34 moves. Therefore, the transfer robot 33 cannot collect the substrate W. In this case, for example, it is preferable to notify a user of an error indicating the projection of the substrate W so that the user can collect the substrate W.

Referring back to FIG. 1, the retreat module 70 connected to the atmospheric transfer module 30 is connected to the other end of the atmospheric transfer chamber 31 in the longitudinal direction, and the substrate W collected by the transfer robot 33 due to the positional misalignment is temporarily stored in the retreat module 70. In other words, when the transfer robot 33 performs an operation of returning the misaligned substrate W to the storage module 60, the positional misalignment of the substrate W is likely to occur again. Therefore, the processing system 1 avoids the positional misalignment in the storage module 60 by loading the substrate W into the retreat module 70 and temporarily storing the substrate W in the retreat module 70.

The retreat module 70 includes, for example, a housing 71 capable of accommodating a substrate W, and a placing table 72 that is disposed in the housing 51 and places thereon the substrate W. The housing 71 is opened toward the atmospheric transfer chamber 31, and the transfer robot 33 can access the inside of the housing 71.

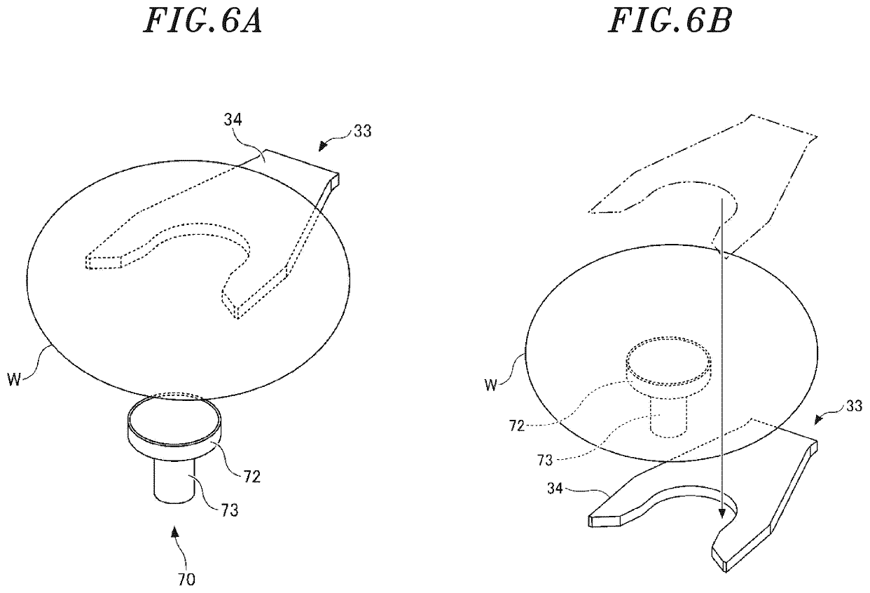

FIG. 6A is a first operation diagram showing the placement of the substrate W on the placing table 72 of the retreat module 70. FIG. 6B is a second operation diagram showing the placement of the substrate W on the placing table 72 of the retreat module 70. The placing table 72 has a flat upper surface, and its outer peripheral surface has a diameter smaller than that of the substrate W. The diameter of the placing table 72 is smaller than the interval between the bifurcated picks 34. The placing table 72 is supported at a predetermined height position in the housing 71 by a support 73 having a diameter smaller than that of the placing table 72.

The transfer robot 33 moves to a position directly above the placing table 72 such that the center of the substrate holding area (the substrate W) of the pick 34 overlaps the upper surface of the placing table 72. Then, the transfer robot 33 places the substrate W on the upper surface of the placing table 72 by lowering the pick 34 downward in the vertical direction. The distance of the downward movement of the pick 34 in the retreat module 70 is set to be longer than that of the pick 34 in the storage module 60. Accordingly, the transfer robot 33 can reliably separate the pick 34 from the substrate W placed on the placing table 72 (i.e., release the contact therebetween).

Referring back to FIG. 1, the controller 90 of the processing system 1 is a computer that includes one or more processors 91, a memory 92, an input/output interface (not shown), and a communication interface (not shown), and controls the entire system. Hereinafter, an example in which the processing system 1 controls operations of individual modules using the controller 90 will be described. Therefore, the controller 90 also functions as a control part of the atmospheric transfer module 30 that is a transfer system. However, the present disclosure is not limited thereto, and the processing system 1 may include a dedicated control part (not shown) for each module, and each control part may operate each module based on a control command from the controller 90.

One or more processors 91 are one of a central processing unit (CPU), a graphics processing unit (GPU), an application specific integrated circuit (ASIC), a field-programmable gate array (FPGA), and a circuit including multiple discrete semiconductors, or combination thereof, and execute a program stored in the memory 92. The memory 92 includes a nonvolatile memory and a volatile memory (for example, a compact disk, a digital versatile disc (DVD), a hard disk, a flash memory, or the like), and forms the storage part of the controller 90.

The controller 90 further includes a user interface 95 that notifies a user of information on the processing system 1 and allows input of information on the processing system 1 based on a user's operation. The user interface 95 may be, e.g., a monitor, a mouse, a keyboard, a touch panel, a speaker, a microphone, or the like.

The processor 91 controls the operation of the transfer robot 33 or the operations of the individual modules by reading out and executing a program stored in the memory 92. Further, functional blocks for monitoring the positional misalignment of the substrate W transferred by the transfer robot 33 and correcting the positional misalignment of the substrate W in controlling the atmospheric transfer module 30 are constructed in the controller 90.

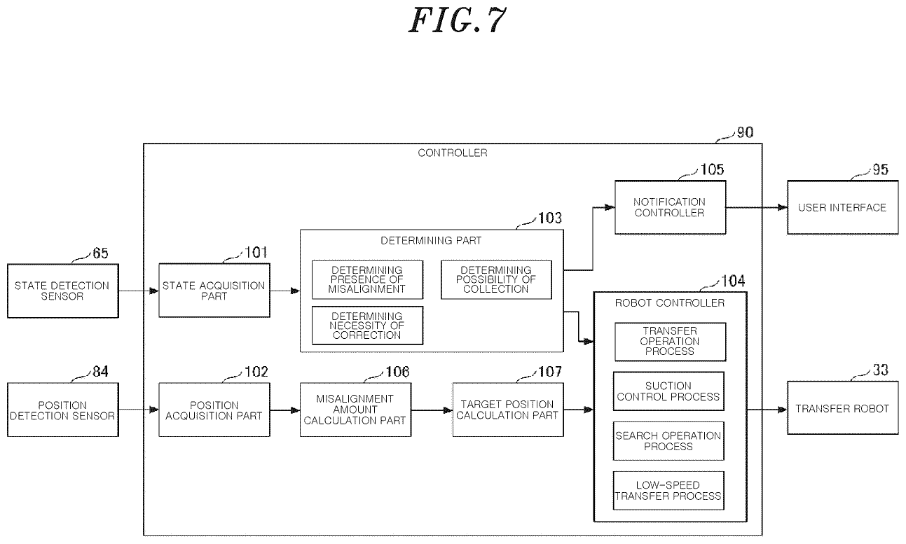

FIG. 7 is a block diagram showing the functional blocks in the controller 90. Specifically, a state acquisition part 101, a position acquisition part 102, a determining part 103, a robot controller 104, a notification controller 105, a misalignment amount calculation part 106, a target position calculation part 107, and the like are formed in the controller 90.

After the substrate W is transferred by the transfer robot 33, the state acquisition part 101 acquires the detection result of the state detection sensor 65 in order to the check the positional misalignment (projection) of substrate W.

The determining part 103 determines whether or not the substrate W is misaligned, whether or not the correction is necessary, and whether or not the substrate W can be collected based on the acquired detection result of the state detection sensor 65. For example, first, the determining part 103 determines whether or not the transferred substrate W is misaligned based on the detection result of the projection determining sensor 66. When the substrate W is misaligned, the determining part 103 determines whether or not it is necessary to collect the substrate W and perform correction based on the detection result of the correction determining sensor 67. Further, the determining part 103 determines whether or not the substrate W can be collected based on the detection result of the collection determining sensor 68.

When the determining part 103 determines that the substrate W cannot be collected, the notification controller 105 notifies a user of an error based on the positional misalignment of the substrate W via the user interface 95. Accordingly, the user can quickly collect the misaligned substrate W.

The robot controller 104 controls the operation of the transfer robot 33. For example, the robot controller 104 performs a transfer operation process for transferring the substrate W from a transfer source module to a transfer destination module. Further, the robot controller 104 performs a suction control process for conducting suction of the substrate W at the timing of receiving the substrate W by the pick 34, and releasing the suction of the substrate W at the timing of delivering the substrate W to/from the pick 34.

In the case of performing correction of the substrate W based on the determination of the determining part 103, the robot controller 104 performs a search operation process for searching for the amount of positional misalignment of the substrate W. In other words, in the case of monitoring the positional misalignment of the substrate W using the state detection sensor 65, the amount of positional misalignment of the substrate W is not detected, so that it is necessary to detect the amount of positional misalignment of the substrate W in order to perform correction of the substrate W.

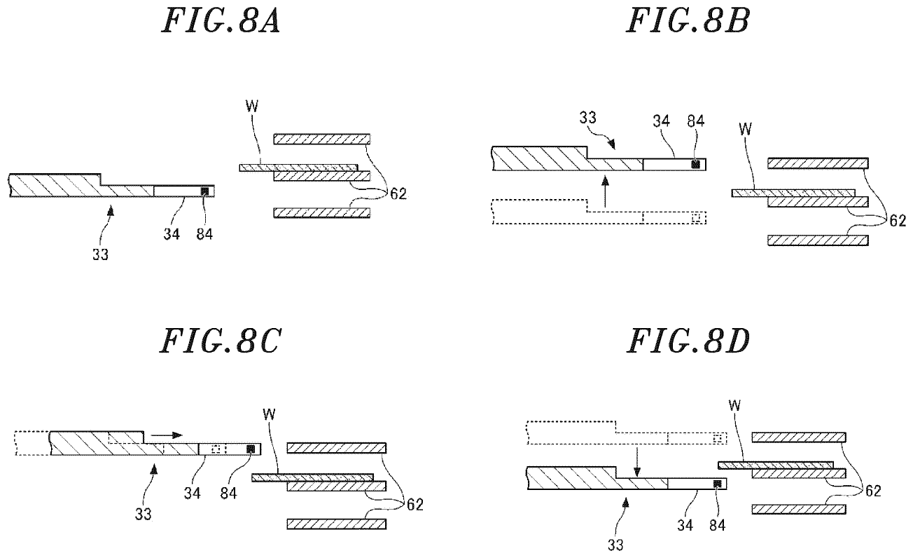

FIGS. 8A to 8D are first to fourth operational diagrams showing the search operation process for detecting the amount of positional misalignment of the substrate W. In the search operation process, the robot controller 104 moves the pick 34 toward the substrate W while vertically moving the substrate W to pass through the reference placing position (height position) of the substrate W supported by the pair of shelf boards 62.

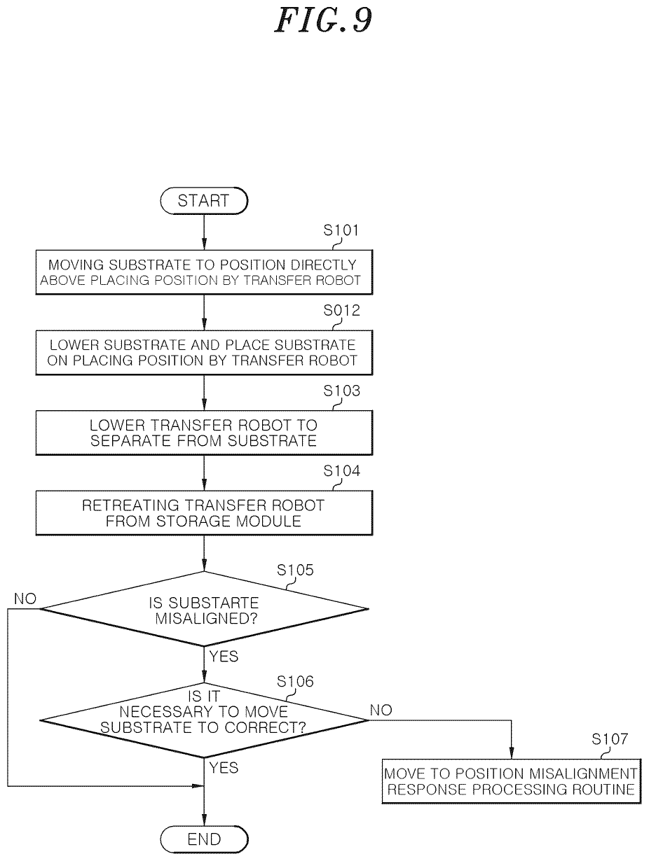

As shown in FIG. 8A, the robot controller 104 moves the pick 34 to the position (for example, the detection position of the collection determining sensor 68) where the misaligned substrate W projects by a maximum distance. At the position where the substrate W projects by the maximum distance, the robot controller 104 moves the pick 34 upward in the vertical direction to pass through the height position of the substrate W from bottom to top, as shown in FIG. 9B. Next, as shown in FIG. 8C, the robot controller 104 moves the pick 34 in the horizontal direction by a preset movement pitch to bring the pick 34 close to the substrate W. Then, as shown in FIG. 8D, the robot controller 104 lowers the pick 34 downward in the vertical direction to pass through the height position of the substrate W from top to bottom (in the vertical direction). When the position detection sensor 84 detects the substrate W while the pick 34 is being lowered, it is determined that the substrate W projects to that position. On the other hand, when the position detection sensor 84 does not detect the substrate W while the pick 34 is being lowered, it is determined that the substrate W does not project to that position. Therefore, the robot controller 104 repeats the operations of FIGS. 8B to 8D until the position detection sensor 84 detects the substrate W. Accordingly, the controller 90 can obtain the amount of positional misalignment of the substrate W accurately.

In the search operation process, the substrate W may be detected by the position detection sensor 84 when the pick 34 is raised from bottom to top (i.e., at the timing shown in FIG. 8A). Further, in the search operation process, in order to accurately detect the amount of positional misalignment of the substrate W, the position of the substrate W may be detected by performing a first search operation of moving the pick 34 toward the substrate W by a first movement pitch that is large and, then, a second search operation of moving the pick 34 toward the substrate W by a second movement pitch smaller than the first movement pitch. For example, the robot controller 104 moves the pick 34 toward the substrate W by every 5 mm as the first movement pitch, and allows the position detection sensor 84 to detect the substrate W. Then, the robot controller 104 retreats the pick 34 by 5 mm (the first movement pitch), moves the pick 34 toward the substrate W by every 1 mm as the second movement pitch, and allows the position detection sensor 84 to detect the substrate W. Accordingly, the controller 90 can obtain the amount of positional misalignment of the substrate W more accurately in a shorter period of time.

Referring back to FIG. 7, the position acquisition part 102 in the controller 90 acquires the detection result of the position detection sensor 84 of the pick 34 in the above-described search operation process. After the search operation process is started, the robot controller 104 terminates the search operation process when the position acquisition part 102 acquires the position of the substrate W.

The misalignment amount calculation part 106 calculates the amount of misalignment of the substrate W based on the detection result of the position detection sensor 84. For example, the misalignment amount calculation part 106 acquires the position information of the position detection sensor 84 of the pick 34 at the time of detecting the substrate W using the position detection sensor 84 from the encoder of the transfer robot 33 or the robot controller 104. Then, the misalignment amount calculation part 106 calculates the amount of positional misalignment of the substrate W based on the acquired position information and pre-obtained information on the reference placing position.

Further, the target position calculation part 107 calculates an adjusted position of the transfer robot 33 at the time of performing the correction of the substrate W using the transfer robot 33 based on the amount of positional misalignment of the substrate W calculated by the misalignment amount calculation part 106. For example, the target position calculation part 107 calculates the target position of the transfer robot by adjusting the amount of positional misalignment of the substrate W in the horizontal direction. The robot controller 104 can accurately collect the misaligned substrate W based on the adjusted position.

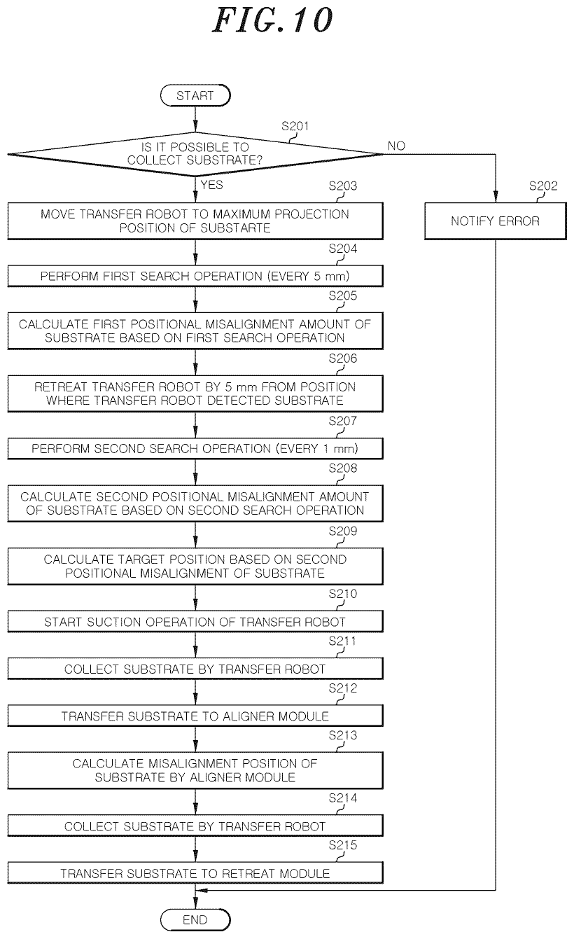

The processing system 1 and the atmospheric transfer module 30 of the present embodiment are basically configured as described above. Hereinafter, an operation (a transfer method) thereof will be described. FIG. 9 is a flowchart showing main process flow of the transfer method. FIG. 10 is a flowchart showing a positional misalignment handling routine.

For example, the robot controller 104 of the controller 90 controls to hold the processed substrate W loaded into the load-lock module 40 with the pick 34 of the transfer robot 33, load the substrate W into the storage module 60 and set the substrate W temporarily in a standby state. At the time of loading the substrate W into the storage module 60, the controller 90 executes respective process flows of FIGS. 9 and 10.

Specifically, the robot controller 104 controls the transfer robot 33 to move the pick 34 and the substrate W to a position directly above the reference placing position where the pair of shelf boards 62 can support the substrate W (step S101).

Next, the robot controller 104 controls the transfer robot 33 to lower the substrate W and place the substrate W on the pair of shelf boards 62 (the placing positions) (step S102). Before or during the downward movement of the substrate W, the robot controller 104 stops suction of the substrate W by the pick 34.

Further, the robot controller 104 lowers the pick 34 of the transfer robot 33 to separate the pick 34 from the substrate W (step S103). Accordingly, the substrate W is placed on the pair of shelf boards 62 in the storage module 60. However, as described above, the pick 34 and the substrate W may be in close contact with each other even after step S103.

The robot controller 104 retreats the transfer robot 33 from the storage module 60 (step S104). If the pick 34 and the substrate W are in close contact with each other or if the substrate W and the pick 34 are close to each other, the substrate W may be misaligned when the transfer robot 33 retreats (see FIGS. 4A and 4B).

The status acquisition part 101 of the controller 90 acquires the detection result of the status detection sensor 65, and allows the determining part 103 to determine whether or not the substrate W is misaligned. The determining part 103 determines whether the substrate W is misaligned based on the detection result of the projection determining sensor 66 (step S105). If the substrate W is misaligned (step $105: YES), the processing proceeds to step S106. On the contrary, if the substrate W is not misaligned (step S105: NO), step S106 is skipped and the transfer method for the storage module 60 is ended.

In step S106, the determining part 103 determines whether or not it is necessary to perform the correction of the substrate W based on the detection result of the correction determining sensor 67. If it is necessary to perform the correction of the substrate W (step S106: YES), the processing proceeds to a positional misalignment handling routine (step S107). On the other hand, if it is not necessary to perform the correction of the substrate W (step S106: NO), the transfer method for the storage module 60 is ended.

As shown in FIG. 10, first, the determining part 103 determines whether or not the substrate W can be collected based on the detection result of the collection determining sensor 68 (step S201). If the substrate W cannot be collected (step S201: NO), the processing proceeds to step S202. If the substrate W can be collected (step S201: YES), the processing proceeds to step S203.

In step S202, the notification controller 105 notifies a user of an error indicating the misalignment of the substrate W via the user interface 95. Accordingly, the user can quickly collect the misaligned substrate W.

On the other hand, if the substrate W can be collected, the controller 90 performs the search operation process for searching for the amount of positional misalignment of the substrate W. Hereinafter, a case where the above-described two-step search operation is performed (the first search operation and the second search operation) will be described.

The robot controller 104 controls the transfer robot 33 to move the pick 34 to the position where the misaligned substrate W projects by a maximum distance (step S203).

Then, the robot controller 104 controls the transfer robot 33 to perform the first search operation (step S204). As described above, in the first search operation, the pick 34 is moved vertically while sliding horizontally by every 5 mm as the first movement pitch, for example. Accordingly, the position detection sensor 84 of the pick 34 detects the position of the substrate W in the first search operation, and the controller 90 controls the position acquisition part 102 to acquire the detection result.

The misalignment amount calculation part 106 calculates a first positional misalignment amount of the substrate W based on the detection result in the first search operation (step S205). Since the unit (the first movement pitch) of the first positional misalignment amount, which is 5 mm, is coarse, the controller 90 performs the second search operation.

The robot controller 104 controls the transfer robot 33 to retreat the pick 34 by 5 mm from the position where the pick 34 detected the substrate in the first search operation (step S206).

Then, the robot controller 104 controls the transfer robot 33 to perform the second search operation (step S207). As described above, in the second search operation, the pick 34 is moved vertically while sliding horizontally by every 1 mm as the second movement pitch, for example. Accordingly, the position detection sensor 84 of the pick 34 detects the position of the substrate W in the second search operation, and the controller 90 controls the position acquisition part 102 to acquire the detection result.

The misalignment amount calculation part 106 calculates a second positional misalignment amount of the substrate W based on the detection result in the second search operation (step S208). The second positional misalignment amount, which is measured by every 1 mm (second movement pitch), has an improved accuracy.

Therefore, the target position calculation part 107 calculates the target position based on the calculated second positional misalignment amount (step S209).

Then, the controller 90 performs an operation of collecting the misaligned substrate W. The robot controller 104 starts suction using the pick 34 of the transfer robot 33 to collect the substrate W (step S210). The suction may be started after the pick 34 is located below the substrate W to be collected.

The robot controller 104 controls the transfer robot 33 to move the pick 34 and collect the misaligned substrate W (step S211). In this case, the robot controller 104 performs the adjustment of the horizontal position of the pick 34 with respect to the substrate W based on the previously calculated target position. Accordingly, the transfer robot 33 can stably hold the substrate W with the pick 34. However, as described above, in the second search operation, the amount of positional misalignment of the substrate W is detected by every 1 mm. Therefore, the substrate W may be misaligned from the pick 34 by 1 mm at most. Hence, the controller 90 transfers the substrate W to the aligner module 50 to eliminate the positional misalignment of the substrate W.

In other words, the robot controller 104 controls the transfer robot 33 to transfer the substrate W to the aligner module 50 (step S212).

Then, in the aligner module 50, the controller 90 controls an optical sensor to detect the center position of the substrate W while rotating the substrate W, thereby calculating the amount of positional misalignment of the substrate W (step S213). The amount of positional misalignment of the substrate W in the aligner module 50 can be more accurate than that in the search operation process.

Therefore, in the case of collecting the substrate W from the aligner module 50, the robot controller 104 performs correction based on the amount of positional misalignment calculated by the aligner module 50, and collects the substrate W (step S214). Therefore, the substrate W held by the pick 34 in the aligner module 50 is no longer misaligned.

Finally, the robot controller 104 transfers the substrate W collected by the aligner module 50 to the retreat module 70, and stores the substrate W in the retreat module 70 (step S215). In the case of lowering the pick 34 with respect to the placing table 72 of the retreat module 70, the pick 34 is lowered by a distance longer than that in the case of lowering the substrate W in the storage module 60. Accordingly, after the substrate W is placed on the placing table 72, the pick 34 is sufficiently separated from the substrate W in a vertically downward direction. Hence, the transfer robot 33 can more reliably release the close contact between the substrate W and the pick 34.

As described above, in the processing system 1 (the atmospheric transfer module 30) and the transfer method, when the substrate W is misaligned, the transfer robot 33 can automatically collect the misaligned substrate W. Accordingly, it is possible to reduce the downtime of the apparatus, and also possible to considerably reduce a user's workload due to positional misalignment of the substrate W.

The processing system 1 (the atmospheric transfer module 30) and the transfer method of the present disclosure are not limited to the above-described embodiments, and may be variously modified. For example, in the processing system 1, after the misaligned substrate W is collected, the substrate W may be transferred to the retreat module 70 without being transferred to the aligner module 50 and subjected to the correction of the positional misalignment. Further, in the processing system 1, after the correction of the positional misalignment is performed in the alignment module 50 (or the storage module 60), the substrate W may be transferred to the transfer destination (target) module without being transferred to the retreat module 70.

In the above embodiment, the case where the positional misalignment of the substrate W, which occurs when the substrate W is loaded into the storage module 60, is monitored and the correction is performed has been described. However, the present disclosure is not limited thereto. In the processing system 1 (the atmospheric transfer module 30) and the transfer method, the same processing may be performed even when the substrate W is loaded into the substrate storage case 39 of the load port 32 or when the substrate W is loaded into the load-lock module 40. Alternatively, in the processing system 1 and the transfer method, the same processing may be performed even when the substrate W is loaded into the processing module 10, the load-lock module 40, or another modules in the vacuum transfer module 20. In other words, the processing module 10, the substrate storage case 39, and the load-lock module 40 also serve as storage parts where the positional misalignment of the substrate W is monitored and the correction is performed.

Further, the object to be transferred by the processing system 1 (the atmospheric transfer module 30) and the transfer method is not limited to the substrate W, but may be various members loaded into and unloaded from the processing module 10 in the processing system 1. For example, the object to be transferred may be an edge ring (not shown) or a cover ring (not shown) placed on the outer periphery of a stage (not shown) of the processing module 10. The edge ring is disposed around the substrate W placed on the stage, and improves the uniformity of processing on the substrate W. The cover ring is disposed at the outer side of the edge ring to suppress the influence of plasma on the stage. In the processing system 1 (the atmospheric transfer module 30) and the transfer method, the edge ring or the cover ring may be stored in the storage part (ring storage module) similarly to the substrate W in the case of transferring the edge ring or the cover ring. In this case, it is possible to detect the positional misalignment of the edge ring or cover ring by the same method s that of the above-described embodiment, and perform appropriate processing (collection, error notification, or the like) depending on the positional misalignment.

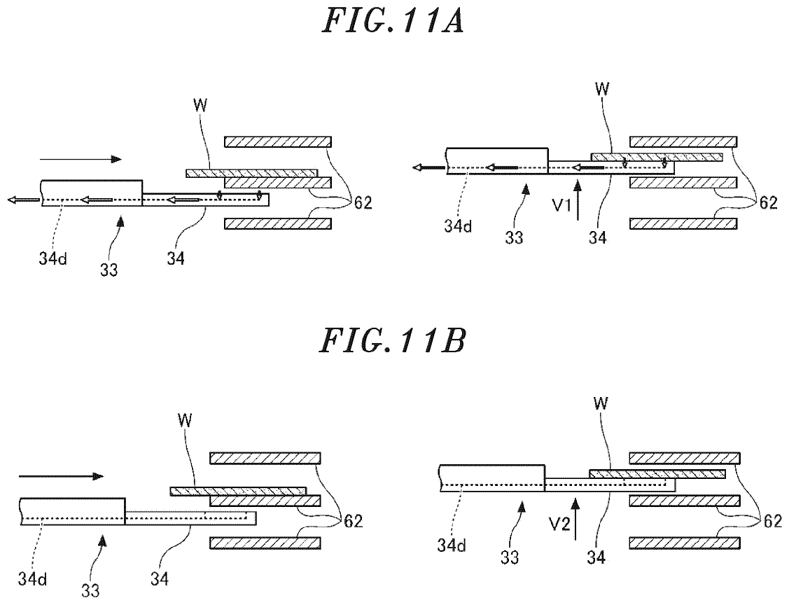

In the above embodiment, as shown in FIG. 11A, the substrate W was attracted by the pick 34 in the case of collecting the misaligned substrate W. However, as shown in FIG. 11B, in the processing system 1 (the atmospheric transfer module 30), the substrate W may not be attracted by the pick 34 in the case of collecting the misaligned substrate W. Further, the processing system 1 may not have a configuration in which the substrate W is attracted by the transfer robot 33. In this case as well, the substrate W may be misaligned due to the close contact with the pick 34. The misalignment of the substrate W can be eliminated by performing the above-described processing.

However, when the substrate W is not attracted, it is preferable to decrease the speed of the operation of collecting the substrate W by the pick 34 and the speed of the operation performed after the substrate W is collected by the pick 34. For example, the controller 90 (the robot controller 104) may set a moving speed V2 of the pick 34 in the case where the substrate W is not attracted to be slower than a moving speed V1 of the pick 34 in the case where the substrate W is attracted (see also a low-speed transfer process of FIG. 7). The moving speed V1 may be the same as the moving speed of the transfer robot 33 at the time of loading the substrate W into the storage module 60 and placing the substrate in the storage module 60. Alternatively, for another example, in order to decrease the speed of the operation of the pick 34, the robot controller 104 may decrease the acceleration of the movement of the pick 34, or may decrease the jerk when the pick 34 is brought into contact with the substrate W or when the pick 34 stops movement.

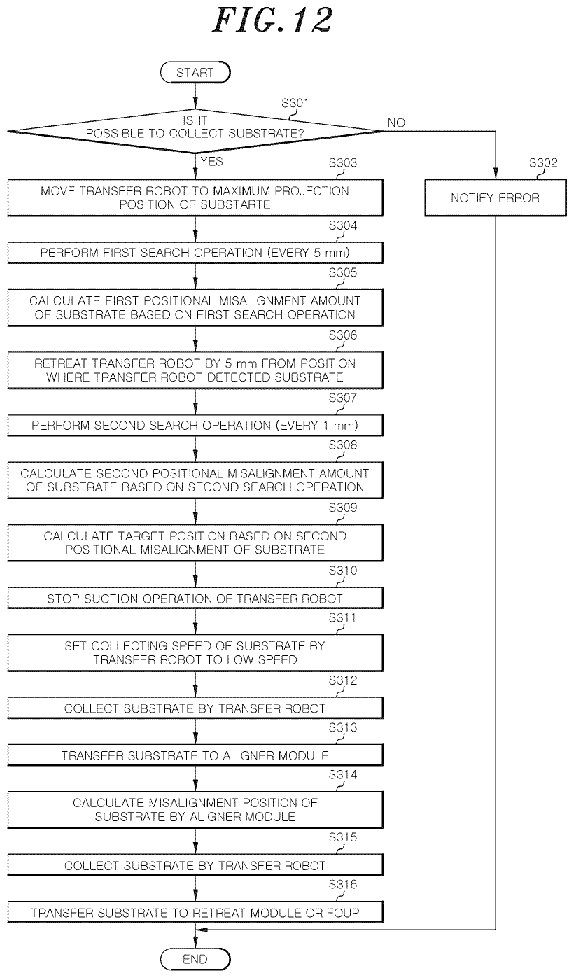

FIG. 12 is a flowchart showing a positional misalignment handling routine of a transfer method according to a modification. Hereinafter, an example of the positional misalignment handling routine performed when the substrate W is not attracted will be described with reference to FIG. 12. In the processing flow of FIG. 12, the processing from step S301 to step S309 may be the same as the processing from step S201 to step S209 in the processing flow of FIG. 9.

When the search operation process in step $309 is completed, the processing proceeds to an operation of collecting the misaligned substrate W. The robot controller 104 stops suction using the pick 34 of the transfer robot 33 at the time of collecting the substrate W (step S310).

Further, the robot controller 104 sets the operation of the transfer robot 33 such that the operation speed (the moving speed V2, the acceleration, and the like) at the time of collecting the substrate W become slower than the operation speed (the moving speed V1, the acceleration, and the like) at the time of loading the substrate W into the storage module 60 (step S311).

The robot controller 104 operates the transfer robot 33 at the decreased operation speed to collect the misaligned substrate W (step S312). In this case, the robot controller 104 performs the adjustment of the horizontal position of the pick 34 with respect to the substrate W based on the previously calculated target position. Accordingly, the transfer robot 33 can stably hold the substrate W with the pick 34.

Then, the robot controller 104 controls the transfer robot 33 to transfer the substrate W to the aligner module 50 (step S313). In this case as well, the robot controller 104 decreases the operation speed (the moving speed V2, the acceleration, and the like) of the pick 34. Accordingly, it is possible to avoid the misalignment of the substrate W during the transfer of the substrate W by the pick 34.

Further, in steps S314 and S315, the same processing as that of steps S213 and S214 of FIG. 9 may be performed.

In the case of collecting the substrate W from the aligner module 50, the robot controller 104 performs correction based on the amount of positional misalignment calculated by the aligner module 50, and moves the pick 34 at the decreased operation speed (the moving speed V2, the acceleration, and the like) to collect the substrate W (step S316). Hence, even in the aligner module 50, the substrate W can be held by the pick 34 without positional misalignment.

Then, the controller 90 controls the transfer robot 33 to transfer the collected substrate W from the aligner module 50 to the retreat module 70 or the substrate storage case 39 (step S316). In other words, in this transfer method, after the misaligned substrate W is collected, the substrate W is not attracted by the pick 34, so that the close contact between the pick 34 and the substrate W is released. Therefore, in the processing system 1, when the substrate W is transferred to the destination module (for example, the substrate storage case 39) as well as the retreat module 70, the substrate W can be placed without positional misalignment.

As described above, in the transfer method according to the modification, when the misaligned substrate W is collected, the substrate W is not attracted by the pick 34, and the operation is performed at a decreased speed. Even in this case, in the processing system 1, the substrate W can be stably collected by the pick 34, and the substrate W whose positional misalignment has been corrected can be transferred to the destination module with high precision.

The above-described embodiments include the following aspects, for example.

### APPENDIX 1

A transfer system comprising:
a transfer robot configured to transfer an object to be transferred;
a storage part configured to store the object to be transferred by the transfer robot;
a state detection sensor configured to detect positional misalignment of the object to be transferred stored in the storage part; and
a controller configured to control an operation of the transfer robot,
wherein the transfer robot has a position detection sensor configured to detect a position of the object to be transferred placed in the storage part, and
the controller controls:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

### APPENDIX 2

The transfer system of Appendix 1, wherein the transfer robot has a bifurcated pick, and has the position detection sensor disposed at the inner side of the bifurcated pick, and
in said detecting the position of the object to be transferred, an operation of vertically moving the transfer robot to pass through a height position of the misaligned object to be transferred and then horizontally moving the transfer robot by a predetermined movement pitch is repeated to bring the position detection sensor close to the misaligned object to be transferred.

### APPENDIX 3

The transfer system of Appendix 2, wherein in said detecting the position of the object to be transferred, a first search operation in which the transfer robot is moved horizontally by a first movement pitch to obtain a first positional misalignment amount is performed and, then, a second search operation in which the transfer robot is moved horizontally by a second movement pitch smaller than the first movement pitch to obtain a second positional misalignment amount is performed.

### APPENDIX 4

The transfer system of Appendix 2 or 3, wherein the position detection sensor transmitting portion configured to emit detection light, and a light receiving portion configured to receive the detection light at a position opposite to the light transmitting portion, and the controller detects the position of the misaligned object to be transferred based on the position of the transfer robot when the detection light is blocked by the object to be transferred.

### APPENDIX 5

The transfer system of any one of Appendices 1 to 4, wherein the state detection sensor includes:
a correction determining sensor configured to detect whether or not a correction for eliminating the misalignment of the object to be transferred by collecting the misaligned object to be transferred is necessary; and
a collection determining sensor configured to detect whether or not the misaligned object to be transferred is collectable, and
the controller executes:
detecting the position of the object to be transferred when it is determined that the correction for eliminating the positional misalignment of the object to be transferred is necessary and that the object to be transferred is collectable.

### APPENDIX 6

The transfer system of Appendix 5, wherein the state detection sensor, the correction determining sensor and the collection determining sensor are sequentially installed in a direction distant from the object to be transferred stored in the storage part.

### APPENDIX 7

The transfer system of any one of Appendices 1 to 6, further comprising:
a retreat module to which the misaligned object to be transferred is stored, and
the controller executes:
transferring, after said collecting the misaligned object to be transferred by the transfer robot, the collected object to be transferred to the retreat module.

### APPENDIX 8

The transfer system of any one of Appendices 1 to 7, wherein the transfer robot is configured to attract and hold the object to be transferred, and
in said collecting the misaligned object to be transferred by the transfer robot, the controller executes:
stopping the attraction of the object to be transferred; and
operating the transfer robot at a speed lower than a speed of placing the object to be transferred in the storage part.

### APPENDIX 9

The transfer system of any one of Appendices 1 to 8, wherein the object to be transferred is one of a substrate, an edge ring, and a cover ring.

### APPENDIX 10

A processing system comprising:
a transfer system including a transfer robot configured to transfer an object to be transferred, a storage part configured to store the object to be transferred by the transfer robot, and a state detection sensor configured to detect positional misalignment of the object to be transferred stored in the storage part;
a processing module to which the object to be processed is transferred via the transfer system; and
a controller configured to control an operation of the transfer robot,
wherein the transfer robot has a position detection sensor configured to detect a position of the object to be transferred placed in the storage part, and
the controller controls:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

### APPENDIX 11

The processing system of Appendix 10, wherein the transfer robot has a bifurcated pick, and the position detection sensor disposed at the inner side of the bifurcated pick, and
in said detecting the position of the object to be transferred, an operation of vertically moving the transfer robot to pass through a height position of the misaligned object to be transferred and then horizontally moving the transfer robot by a predetermined movement pitch is repeated to bring the position detection sensor close to the misaligned object to be transferred.

### APPENDIX 12

The processing system of Appendix 11, wherein in said detecting the position of the object to be transferred,
a first search operation in which the transfer robot is moved horizontally by a first movement pitch to obtain a first positional misalignment amount is performed and, then, a second search operation in which the transfer robot is moved horizontally by a second movement pitch smaller than the first movement pitch to obtain a second positional misalignment amount is performed.

### APPENDIX 13

The processing system of Appendix 11 or 12, wherein the position detection sensor includes a light transmitting portion configured to emit detection light, and a light receiving portion configured to receive the detection light at a position opposite to the light transmitting portion, and
the controller detects the position of the misaligned object to be transferred based on the position of the transfer robot when the detection light is blocked by the object to be transferred.

### APPENDIX 14

The processing system of any one of Appendices 10 to 13, wherein the state detection sensor includes:
a correction determining sensor configured to detect whether or not a correction for eliminating the misalignment of the object to be transferred by collecting the misaligned object to be transferred is necessary; and
a collection determining sensor configured to detect whether or not the misaligned object to be transferred is collectable, and
the controller executes:
detecting the position of the object to be transferred when it is determined that the correction for eliminating the positional misalignment of the object to be transferred is necessary and that the object to be transferred is collectable.

### APPENDIX 15

The processing system of Appendix 14, wherein the state detection sensor, the correction determining sensor and the collection determining sensor are sequentially installed in a direction distant from the object to be transferred stored in the storage part.

### APPENDIX 16

The processing system of any one of Appendices 10 to 14, further comprising:
a retreat module to which the misaligned object to be transferred is stored, and
the controller executes:
transferring, after said collecting the misaligned object to be transferred by the transfer robot, the collected object to be transferred to the retreat module.

### APPENDIX 17

The processing system of any one of Appendices 10 to 16, wherein the object to be transferred is one of a substrate, an edge ring, and a cover ring.

### APPENDIX 18

A transfer method comprising:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

### APPENDIX 19

The transfer method of Appendix 18, wherein the object to be transferred is one of a substrate, an edge ring, and a cover ring.

The processing system 1, the transfer system, and the transfer method of the above-described embodiments are illustrative in all respects and are not restrictive. The embodiments may be variously modified and improved without departing from the scope of the appended claims and the gist thereof. The above-described embodiment may include other configurations without contradicting each other and may be combined without contradicting each other.

1. A transfer system comprising:
a transfer robot configured to transfer an object to be transferred;
a storage part configured to store the object to be transferred by the transfer robot;
a state detection sensor configured to detect positional misalignment of the object to be transferred stored in the storage part; and
a controller configured to control an operation of the transfer robot,
wherein the transfer robot has a position detection sensor configured to detect a position of the object to be transferred placed in the storage part, and
the controller controls:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

2. The transfer system of claim 1, wherein the transfer robot has a bifurcated pick, and has the position detection sensor disposed at the inner side of the bifurcated pick, and
in said detecting the position of the object to be transferred, an operation of vertically moving the transfer robot to pass through a height position of the misaligned object to be transferred and then horizontally moving the transfer robot by a predetermined movement pitch is repeated to bring the position detection sensor close to the misaligned object to be transferred.

3. The transfer system of claim 2, wherein in said detecting the position of the object to be transferred, a first search operation in which the transfer robot is moved horizontally by a first movement pitch to obtain a first positional misalignment amount is performed and, then, a second search operation in which the transfer robot is moved horizontally by a second movement pitch smaller than the first movement pitch to obtain a second positional misalignment amount is performed.

4. The transfer system of claim 2, wherein the position detection sensor includes a light transmitting portion configured to emit detection light, and a light receiving portion configured to receive the detection light at a position opposite to the light transmitting portion, and
the controller detects the position of the misaligned object to be transferred based on the position of the transfer robot when the detection light is blocked by the object to be transferred.

5. The transfer system of claim 1, wherein the state detection sensor includes:
a correction determining sensor configured to detect whether or not a correction for eliminating the misalignment of the object to be transferred by collecting the misaligned object to be transferred is necessary; and
a collection determining sensor configured to detect whether or not the misaligned object to be transferred is collectable, and
the controller executes:
detecting the position of the object to be transferred when it is determined that the correction for eliminating the positional misalignment of the object to be transferred is necessary and that the object to be transferred is collectable.

6. The transfer system of claim 5, wherein the state detection sensor, the correction determining sensor and the collection determining sensor are sequentially installed in a direction distant from the object to be transferred stored in the storage part.

7. The transfer system of claim 1, further comprising:
a retreat module to which the misaligned object to be transferred is stored, and
the controller executes:
transferring, after said collecting the misaligned object to be transferred by the transfer robot, the collected object to be transferred to the retreat module.

8. The transfer system of claim 1, wherein the transfer robot is configured to attract and hold the object to be transferred, and
in said collecting the misaligned object to be transferred by the transfer robot, the controller executes:
stopping the attraction of the object to be transferred; and
operating the transfer robot at a speed lower than a speed of placing the object to be transferred in the storage part.

9. The transfer system of claim 1, wherein the object to be transferred is one of a substrate, an edge ring, and a cover ring.

10. A processing system comprising:
a transfer system including a transfer robot configured to transfer an object to be transferred, a storage part configured to store the object to be transferred by the transfer robot, and a state detection sensor configured to detect positional misalignment of the object to be transferred stored in the storage part;
a processing module to which the object to be processed is transferred via the transfer system; and
a controller configured to control an operation of the transfer robot,
wherein the transfer robot has a position detection sensor configured to detect a position of the object to be transferred placed in the storage part, and
the controller controls:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

11. The processing system of claim 10, wherein the transfer robot has a bifurcated pick, and the position detection sensor disposed at the inner side of the bifurcated pick, and
in said detecting the position of the object to be transferred, an operation of vertically moving the transfer robot to pass through a height position of the misaligned object to be transferred and then horizontally moving the transfer robot by a predetermined movement pitch is repeated to bring the position detection sensor close to the misaligned object to be transferred.

12. The processing system of claim 11, wherein in said detecting the position of the object to be transferred,
a first search operation in which the transfer robot is moved horizontally by a first movement pitch to obtain a first positional misalignment amount is performed and, then, a second search operation in which the transfer robot is moved horizontally by a second movement pitch smaller than the first movement pitch to obtain a second positional misalignment amount is performed.

13. The processing system of claim 11, wherein the position detection sensor includes a light transmitting portion configured to emit detection light, and a light receiving portion configured to receive the detection light at a position opposite to the light transmitting portion, and
the controller detects the position of the misaligned object to be transferred based on the position of the transfer robot when the detection light is blocked by the object to be transferred.

14. The processing system of claim 10, wherein the state detection sensor includes:
a correction determining sensor configured to detect whether or not a correction for eliminating the misalignment of the object to be transferred by collecting the misaligned object to be transferred is necessary; and
a collection determining sensor configured to detect whether or not the misaligned object to be transferred is collectable, and
the controller executes:
detecting the position of the object to be transferred when it is determined that the correction for eliminating the positional misalignment of the object to be transferred is necessary and that the object to be transferred is collectable.

15. The processing system of claim 14, wherein the state detection sensor, the correction determining sensor and the collection determining sensor are sequentially installed in a direction distant from the object to be transferred stored in the storage part.

16. The processing system of claim 10, further comprising:
a retreat module to which the misaligned object to be transferred is stored, and
the controller executes:
transferring, after said collecting the misaligned object to be transferred by the transfer robot, the collected object to be transferred to the retreat module.

17. The processing system of claim 10, wherein the object to be transferred is one of a substrate, an edge ring, and a cover ring.

18. A transfer method comprising:
transferring the object to be transferred by the transfer robot and placing the object to be transferred in the storage part;
determining, after said placing the object to be transferred, whether or not the misaligned object to be transferred is collectable based on the detection result of the state detection sensor;
operating the transfer robot and detecting the position of the object to be transferred by the position detection sensor when it is possible to collect the misaligned object to be transferred; and
moving the transfer robot based on the detected position of the object to be transferred and collecting the misaligned object to be transferred by the transfer robot.

19. The transfer method of claim 18, wherein the object to be transferred is one of a substrate, an edge ring, and a cover ring.
